(19) United States
(12) Patent Application Publication
(10) Pub. No.: US 2009/0141502 A1
(43) Pub. Date: Jun. 4, 2009

(54) LIGHT OUTPUT ENHANCED GALLIUM NITRIDE BASED THIN LIGHT EMITTING DIODE

(75) Inventors: Junichi Sonoda, Goleta, CA (US); Shuji Nakamura, Santa Barbara, CA (US); Kenji Iso, Fujisawa (JP); Steven P. DenBaars, Goleta, CA (US); Makoto Saito, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/325,939

(22) Filed: Dec. 1, 2008

Related U.S. Application Data
(60) Provisional application No. 60/991,625, filed on Nov. 30, 2007.

(51) Int. Cl. H01L 33/00; H01L 21/20

(52) U.S. Cl. 362/311.02; 257/98; 438/29; 257/E33.068; 257/E21.09; 257/E33.067

(57) ABSTRACT

A gallium nitride (GaN) based light emitting device, wherein the device comprises a first surface and a second surface, and the first surface and second surface are separated by a thickness of less than 100 micrometers, and preferably less than 20 micrometers. The first surface may be roughened or textured. A silver or silver alloy may be deposited on the second surface. The second surface of the device may be bonded to a permanent substrate.

### CROSS REFERENCE TO RELATED APPLICATIONS

This application claims the benefit under 35 U.S.C. Section 119(e) of co-pending and commonly-assigned U.S. Provisional Patent Application Ser. No. 60/991,625, filed on Nov. 30, 2007, by Junichi Sonoda, Shuji Nakamura, Kenji Iso, Steven P. DenBaars, and Makoto Saito, entitled “LIGHT OUTPUT ENHANCED GALLIUM NITRIDE BASED THIN LIGHT EMITTING DIODE,” attorneys' docket number 30794.250-US-P1 (2008-197-1), which application is incorporated by reference herein.

This application is related to the following co-pending and commonly-assigned U.S. patent applications:

U.S. Utility application Ser. No. 11/510,240, filed on Aug. 25, 2006, by P. Morgan Pattison, Rajat Sharma, Steven P. DenBaars, and Shuji Nakamura entitled “SEMICONDUCTOR MICRO-CAVITY LIGHT EMITTING DIODE,” attorney's docket number 30794.146-US-U1 (2006-017-2), which application claims the benefit under U.S.C. Section 119(e) of U.S. Provisional Application Ser. No. 60/711,940, filed on Aug. 26, 2005, by P. Morgan Pattison, Rajat Sharma, Steven P. DenBaars, and Shuji Nakamura entitled “SEMICONDUCTOR MICRO-CAVITY LIGHT EMITTING DIODE,” attorney's docket number 30794.146-US-P1 (2006-017-1);

which applications are incorporated by reference herein.

### BACKGROUND OF THE INVENTION

1. Field of the Invention

This invention relates to enhancing both light extraction and internal quantum efficiency of light emitting devices.

2. Description of the Related Art

A lower dislocation crystal is required to obtain higher efficiency light output. The development of the gallium nitride (GaN) free standing substrate (FSS) has provided low dislocation crystals and high internal quantum efficiency (IQE) devices. FIGS. 1a and 1b show a conventional GaN light emitting diode (LED) that was grown on a GaN FSS 102, for example, an n-GaN substrate, wherein FIG. 1b is a cross sectional diagram of the LED along line A-A′ of the LED in FIG. 1a.

The LED comprises an n-GaN layer 104, active layer 106 and p-GaN layer 108 on the substrate 102. The LED (together with the substrate 102) has a thickness 110 (including the substrate 102) between 300 micrometers (μm) and 400 μm, length 112 between 300 μm and 400 μm, and width 114 between 300 μm and 400 μm. However, light extraction efficiency (LEE) is decreased through the GaN crystal due to free carrier absorption. The absorption coefficient is around a=3 cm⁻¹ for n-type GaN, which has a 1×10¹⁸ cm³ electron concentration (N_{d}). Light intensity decreases 10% with each passing through the 350 micrometers thick GaN bulk 102. The device also has an indium-tin-oxide (ITO) layer 116, bonding pad 118, and n-electrode 120.

FIG. 2 is a schematic illustrating a light emitting device with a GaN substrate 200, active layer 202 on the substrate 200, and mirror 204 on the substrate 200. FIG. 2 shows a simple model considering the light absorption by free carriers in a GaN substrate 200, wherein a ray of light 206 emitted by the active layer 202 is reflected by a mirror 204 (having R=100% reflection) to form a reflected ray 208 which has an intensity decreased to 80% when it impinges on the surface 210 (i.e., 20% of intensity is lost by free carrier absorption).

Specifically, the intensity at the surface 210 is calculated to be:

I=Iₒe^{-ax}=Iₒe^{3×0.07}=0.8Iₒ

where Iₒ is the intensity of the light emitted at the active layer 202 at position 212, x is the distance the light travels in ray 206 and ray 208 after emission by the active layer 202 (approximately twice the thickness 214 of the device, wherein the device has a thickness 214 of 350 μm, so that x˜0.035 cm×2˜0.7 cm), and a=3 cm⁻¹ is the absorption coefficient for GaN with N_{d}=1×10¹⁸ cm⁻³. As a result, there is only a little advantage to using a device using a GaN FSS over a commercial device which does not use a FSS.

On the other hand, a roughened or structured surface is employed to create a high LEE value. FIGS. 3a and 3b show a thin film LED 300, with an active layer 302, mirror 304, thickness 306 of approximately 5 μm, and length 308 of approximately 350 μm. Light 310 emitted by the active layer 302 is totally internally reflected at a first surface 312 of the LED (and reflected at a second surface 314 of the LED which has the mirror 304), but in FIG. 3b surface roughening 316 of the surface 312 enhances extraction 318 of light 310 which has been emitted by the active region 302 (FIG. 3b is the LED 300 of FIG. 3a after surface roughening 316 of the surface 312). The critical angle is approximately 34 degrees for an escape cone from GaN (refractive index n=2.5) to resin (refractive index n=1.4). FIG. 3a and FIG. 3b show the LEE improvement for a thin film LED 300 using surface roughening 316. This type of LED was grown on a sapphire substrate, wherein a substrate lift off was performed by a laser lift off technique. The dislocation density is still high and internal efficiency is low.

The purpose of the present invention is to enhance both light extraction and quantum efficiency.

### SUMMARY OF THE INVENTION

The present invention describes a GaN based LED, wherein a low dislocation crystal is grown by Metal-Organic Chemical Vapour Deposition (MOCVD) on a GaN FSS, wherein the device is made thinner to prevent internal light absorption. To enhance light output even more, a surface of the LED is roughened into a hexagonal shaped cone or other shaped structure and another surface of the LED is attached to a silver or silver-containing alloy acting as a mirror. This structure provides both a high LEE and a high IQE. The present invention is a pathway to high efficiency light emitting devices.

Therefore, to overcome the limitations in the prior art described above, and to overcome other limitations that will become apparent upon reading and understanding the present specification, the present invention describes a III-nitride based light emitting device comprising an active region for emitting light; one or more thicknesses of III-nitride between the active region and one or more light extraction or reflection surfaces of the light emitting device, such that an intensity of the light at the extraction surfaces is attenuated by no more than 5% as compared to the intensity of the light at the active region, wherein the attenuation is due to absorption of the light by the III-nitride.

The III-nitride may comprise the active region between a p-type layer and an n-type layer, the light extraction surfaces may be a first surface of the III-nitride and a second surface of the III-nitride, the active region may comprise an epitaxial growth having a growth direction, and the thicknesses may be such that (1) a first distance along the growth direction between the first surface and the second surface is less than 100 micrometers, and (2) the light emitted by the active region in a direction parallel to the growth direction travels a second distance within the III-nitride of at most twice the first distance.

Typically, the first surface is roughened or textured, and the second surface is a surface of a metal mirror deposited on the p-type layer and bonded to a permanent substrate. In this case, the first distance may be less than 20 micrometers. Furthermore, the n-type layer is typically on a substrate, and the first surface is a surface of the substrate.

The present invention further discloses a method for increasing internal quantum efficiency (IQE) of a III-nitride light emitting device by reducing re-absorption of light by the device, comprising: providing an active region for emitting the light; and providing one or more thicknesses of III-nitride between the active region and one or more light extraction or reflection surfaces of the light emitting device, wherein the thicknesses are such that an intensity of the light at the extraction surfaces is attenuated by no more than 5% as compared to the intensity of the light at the active region, wherein the attenuation is due to absorption of the light by the III-nitride.

Finally, the present invention discloses a method for emitting light from a light emitting device with increased internal quantum efficiency, comprising: emitting light from an active region of the device, wherein one or more thicknesses of III-nitride, between the active region and one or more light extraction or reflection surfaces of the light emitting device, are such that an intensity of the light at the extraction surfaces is attenuated by no more than 5% as compared to the intensity of the light at the active region, wherein the attenuation is due to absorption of the light by the III-nitride.

### BRIEF DESCRIPTION OF THE DRAWINGS

Referring now to the drawings in which like reference numbers represent corresponding parts throughout:

FIG. 1a is a schematic diagram for a GaN LED using a GaN substrate and FIG. 1b is a cross-sectional diagram along the line A-A′ of the LED shown in FIG. 1a.

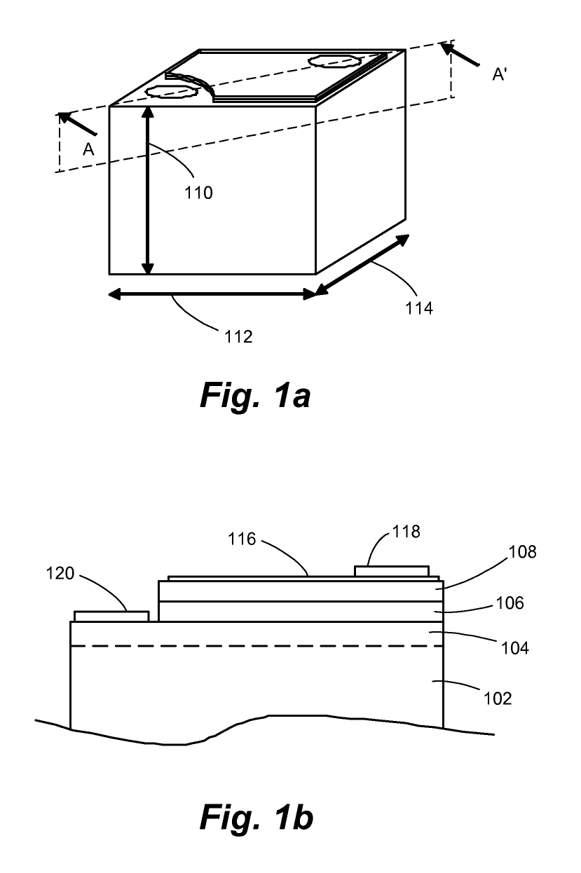

FIG. 2 is a simple model considering light absorption by free carriers in a GaN substrate, wherein a ray reflected by a mirror has an intensity decreased to 80% when it impinges on the surface (i.e. 20% of intensity is lost by free carrier absorption).

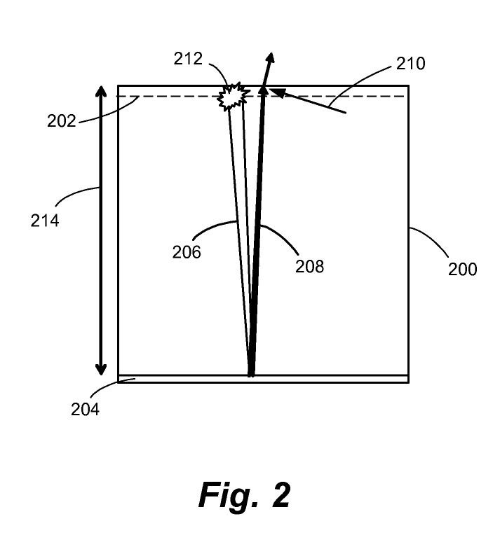

FIGS. 3a and 3b are schematics showing a LEE improvement for a thin film LED using surface roughening, wherein this type of LED was grown on a sapphire substrate, the substrate was lifted off using a laser lift off technique, the dislocation density is still high and internal efficiency is low.

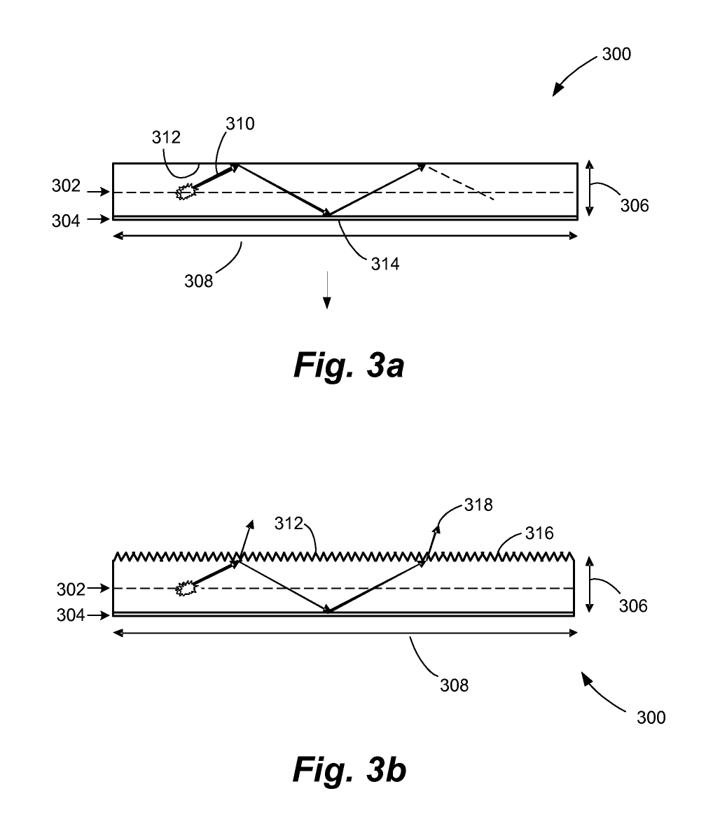

FIGS. 4a-4e illustrate a method for fabricating the device of the present invention.

FIG. 5 is a graph plotting light attenuation (arbitrary units. a.u.) as function of distance traveled by light through GaN, wherein 1.00 signifies no attenuation and 0.95 signifies 5% attenuation.

FIG. 6 is a cross sectional diagram for a device embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

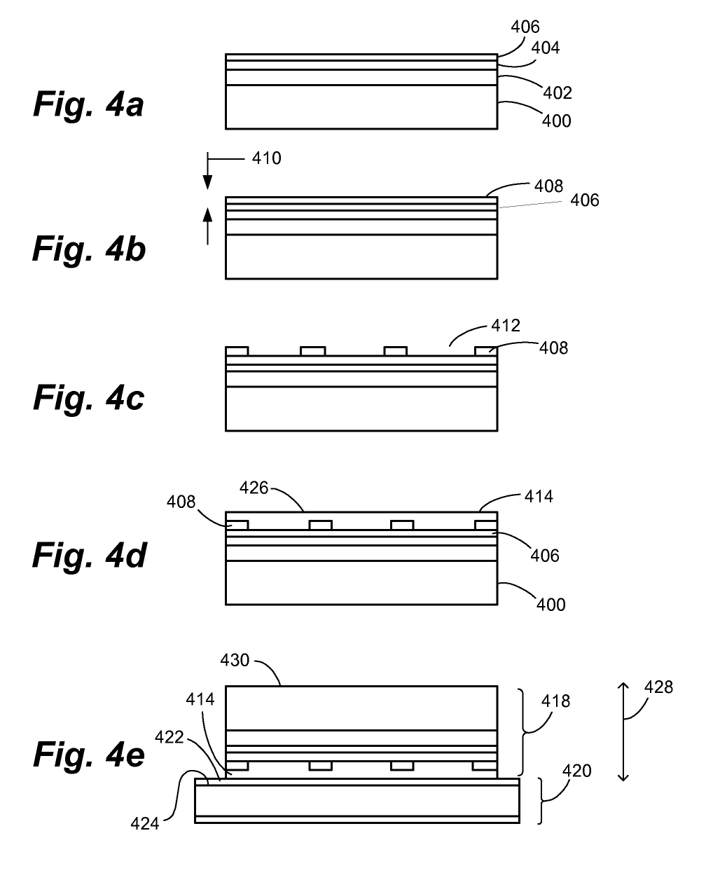

To keep both IQE and LEE high, the present invention uses a GaN FSS which is made thinner. FIGS. 4a-4e illustrate a process for fabricating a device according to the preferred embodiment of the present invention.

FIG. 4a represents the step of MOCVD growth, comprising selecting a GaN substrate 400 having a desired crystallographic plane (non-polar, semi-polar or polar planes, for example) and growing a GaN LED structure on the substrate 400. The GaN substrate 400 may be a temporary substrate such as a GaN FSS. Basic growth layers comprise at least n-GaN 402, an InGaN multi quantum well (MQW) as an active layer 404, and p-GaN 406. However, it is also possible to insert AlGaN or/and some super lattice structure for further investigation of the IQE.

FIG. 4b illustrates the step of a silicon dioxide (SiO₂) layer 408 being deposited (on the p-GaN 406) by Electron Beam (EB) (or any similar technique) to prevent metal sputtering during Reactive Ion Etching (RIE). The SiO₂ film thickness 410 is around 100 nm. If RIE is not used, the SiO₂ film 408 is not required.

FIG. 4c illustrates the step of patterning the SiO₂ 408 to open windows 412 in the SiO₂ film 408.

FIG. 4d illustrates the step of mirror electrode formation. After opening the windows 412 in the SiO₂ film 408, silver film 414 is deposited by EB on the p-GaN 406 to make a mirror and ohmic contact to the p-GaN 406. To improve bonding quality, the silver 414 may be deposited with Ni, Ti W, Pt, Pd or Au.

FIG. 4e illustrates the step of wafer bonding, for example, at 300° C. This step comprises preparing a substrate to support the thin LED 418 (comprising n-GaN 402, active layer 404, p-GaN 406, SiO₂ 408, windows 412, and silver 414) as a permanent substrate 420. The present invention selects a Si wafer as the support substrate/permanent substrate 420. The Au-30 wt % Sn alloy 422 is deposited on one of surfaces 424 of the permanent substrate 420 in order to solder bond the Si wafer to the LED 418. The GaN LED wafer 418 is positioned up-side-down and the silver face 426 of the LED 418 is attached to the Au-30 wt % Sn alloy 422 on the permanent substrate 420. Force is added and the temperature is increased up to around 300° C. to bond both the Si wafer 420 and the GaN wafers 418.

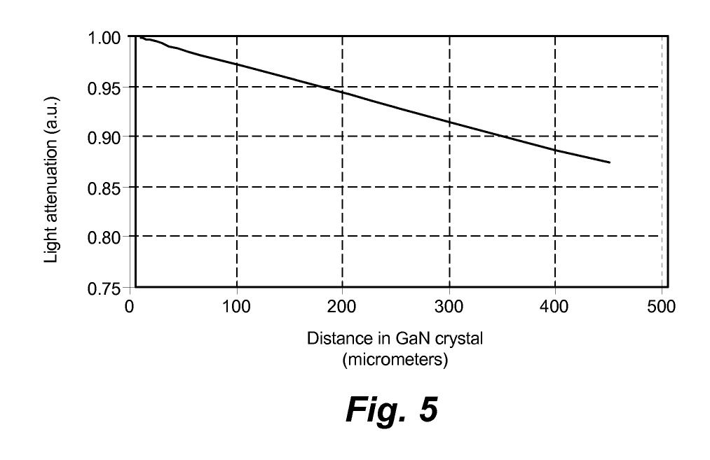

A grind and polish step (not shown) is then used to thin at least part of the GaN LED 418. The thickness 428 of the LED 418 must be at most 100 microns, although it is desirable that the thickness 428 should be less than 20 microns. The influence of absorption is almost eliminated for a thickness 428 less than 20 micron. FIG. 5 shows light attenuation in a GaN crystal for an absorption coefficient α=3 cm⁻¹.

A roughened surface 430 is then employed to decrease multiple reflections in the GaN LED, in order to increase the light extraction.

After the surface roughening step, a Ti/Al/Au electrode is formed to make ohmic contact to the n-type GaN 404 using an EB evaporator and furnace annealler (not shown). Then, in order to separate each LED chip, saw streets are opened between the chips using RIE and cut using a dicing saw machine.

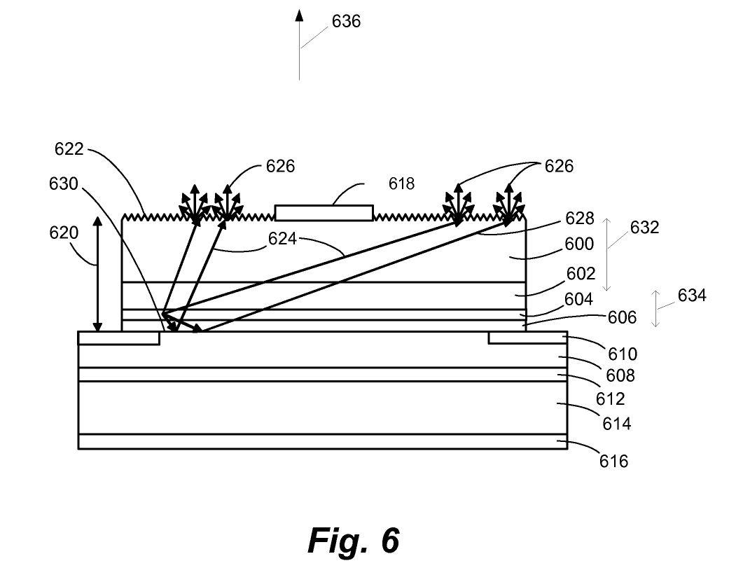

FIG. 6 is a cross sectional diagram for a light emitting device according to the preferred embodiment of the present invention. The device comprises n-GaN (part of the substrate) 600, n-GaN layer (epitaxial growth layer) 602, active layer 604, p-GaN layer 606, mirror electrode (silver alloy) 608, SiO₂ 610, solder layer (Au—Sn) 612, permanent substrate (silicon) 614, back side electrode 616 (e.g. Al, Au, Pt, Ni, Ti or their alloy which can make ohmic contact to the permanent substrate), and electrode 618 (e.g. Ti/Al or their metal). The device has a thickness 620 of around 20 microns and a roughened surface 622 of the n-GaN substrate 600. Light 624 emitted by the active layer 604 is extracted 626 at the roughened surface 622 and reflected 628 by the mirror 608 (or mirror surface 630).

Thus, FIGS. 5 and 6 illustrate an example of a III-nitride based light emitting device comprising an active region 604 for emitting light 624; and one or more thicknesses 632, 634 of III-nitride between the active region 604 and one or more light extraction surfaces 622 or reflection surfaces 630 of the light emitting device, wherein the thicknesses 632, 634 are such that an intensity of the light at the extraction surfaces 622 is attenuated by no more than 5% as compared to the intensity of the light at the active region 604, wherein the attenuation is due to absorption of the light by the III-nitride.

For example, the III-nitride may comprise the active region 604 between a p-type layer 606 and an n-type layer 602, the light extraction surfaces may be a first surface 622 of the III-nitride and a second surface 630 of the III-nitride, the active region 604 may comprise an epitaxial growth having a growth direction 636, and the thicknesses 632, 634 may be such that a first distance 620, parallel to the growth direction 636 and between the first surface 622 and the second surface 630, is less than 100 micrometers, and the light emitted by the active region in a direction parallel to the growth direction 636 travels a second distance within the III-nitride of at most twice the first distance 620. The second surface 630 may be a surface of a metal mirror 608 (having at least 70% reflectivity for the light, for example) deposited on the p-type layer 606 and bonded to a permanent substrate 614. The first surface 622 may be a surface of a substrate 600.

Possible Modifications and Variations

It is possible to change the order of the process steps from bonding followed by grinding, to grinding followed by bonding, wherein a thickness of at least around 100 microns is selected.

The bonding method is possible using not only eutectic bonding, but also anodic bonding, glue bonding or direct bonding, for example.

While the present invention discusses an InGaN MQW layer as an active region, other active region materials consistent with III-nitride or GaN related compound semiconductor LEDs may also be used. The LED may comprise n-type and p-type layers made from III-nitride material, and additional device layers consistent with III-nitride LED fabrication, wherein III-nitrides are also referred to as Group III nitrides, or just nitrides, or by (Al,Ga,In,B)N, or by Al_{(1-x-y)}In_{y}GaₓN where 0≦x≦1 and 0≦y≦1.

The present invention may use permanent substrates other than Si wafers, and solder metals other than Au/Sn. The GaN substrate may be thinned across its entire surface or only part of the surface. Other reflective metals other than silver or silver alloys may be used for the mirror, for example.

The present invention is not limited to III-nitride light emitting devices, but can be applied to light emitting devices which would benefit from reduced thickness to reduce absorption by the substrate.

With regard to the thickness of a device, thinner is better, to reduce absorption loss in the LEDs. However, because of the handling processes used, the GaN substrate should usually be no thinner than approximately 50-100 microns. If the GaN substrate is thinner than this value, it can be easily cracked during handling. However, after bonding the thin GaN substrate onto another material substrate, any thickness (for example, less than 20 microns) may be used.

With regard to absorption loss, and more specifically, free carrier absorption, the origin of the large absorption losses due to the GaN substrate is not currently known. For examples, when a blue LED is fabricated on a GaN substrate, the emission wavelength of the blue LED is 450 nm, which should be transparent for the GaN substrate, because GaN has a bandgap energy of 3.4 eV (360 nm). If the emission wavelength is shorter than 360 nm, a large absorption loss is observed. However, even for blue emissions, there is a relatively large absorption due to the GaN substrate.

Advantages and Improvements

Compared with existing methods and devices, light output in the present invention should be enhanced because both IQE and LEE are kept high using low dislocation GaN FSS and a thinning process.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based light emitting device comprising:
an active region for emitting light;
one or more thicknesses of III-nitride between the active region and one or more light extraction or reflection surfaces of the light emitting device, such that an intensity of the light at the extraction surfaces is attenuated by no more than 5% as compared to the intensity of the light at the active region, wherein attenuation is due to absorption of the light by the III-nitride.

2. The device of claim 1, wherein:
the III-nitride comprises the active region between a p-type layer and an n-type layer,
the light extraction surfaces are a first surface of the III-nitride and a second surface of the III-nitride,
the active region comprises an epitaxial growth having a growth direction, and
the thicknesses are such that:
(1) a first distance along the growth direction between the first surface and the second surface is less than 100 micrometers, and
(2) the light emitted by the active region in a direction parallel to the growth direction travels a second distance within the III-nitride of at most twice the first distance.

3. The device of claim 2, wherein the first surface is roughened or textured.

4. The device of claim 3, wherein the second surface is a surface of a metal deposited on the p-type layer, and the metal has at least 70% reflectivity for the light.

5. The device of claim 4, wherein the metal is silver or a silver based alloy.

6. The device of claim 4, wherein the second surface of the device is bonded to a permanent substrate.

7. The device of claim 6, wherein the first distance is less than 20 micrometers.

8. The device of claim 6, wherein the n-type layer is on a substrate, the first surface is a surface of the substrate, and the n-type layer, active region, and p-type layer comprise a III-nitride material.

9. A method for increasing internal quantum efficiency (IQE) of a III-nitride light emitting device by reducing re-absorption of light by the device, comprising:
providing an active region for emitting the light; and
providing one or more thicknesses of III-nitride between the active region and one or more light extraction or reflection surfaces of the light emitting device, such that an intensity of the light at the extraction surfaces is attenuated by no more than 5% as compared to the intensity of the light at the active region, wherein attenuation is due to absorption of the light by the III-nitride.

10. A method for emitting light from a light emitting device with increased internal quantum efficiency, comprising:
emitting light from an active region of the device, wherein one or more thicknesses of III-nitride, between the active region and one or more light extraction or reflection surfaces of the light emitting device, are such that an intensity of the light at the extraction surfaces is attenuated by no more than 5% as compared to the intensity of the light at the active region, wherein attenuation is due to absorption of the light by the III-nitride.

11. A III-nitride based light emitting device comprising:
a first surface for extracting light and a second surface for extracting light or redirecting light towards the first surface, wherein the first surface and second surface are separated by a thickness of less than 100 micrometers.
